(19) United States
(12) Patent Application Publication
(10) Pub. No.: US 2012/0007466 A1
(43) Pub. Date: Jan. 12, 2012

(54) PRINTED-CIRCUIT BOARD AND VIBRATION MOTOR HAVING THE SAME

(75) Inventor: Sang Gil An, Gyunggi-do (KR)

(73) Assignee: SAMSUNG ELECTRO-MECHANICS CO., LTD., Gyunggi-do (KR)

(21) Appl. No.: 12/941,819

(22) Filed: Nov. 8, 2010

(30) Foreign Application Priority Data
Jul. 8, 2010 (KR) 1020100065881

(51) Int. Cl. H01R 39/06; H05K 1/09

(52) U.S. Cl. 310/237; 174/257

(57) ABSTRACT

The printed-circuit board according to the present invention includes a base member, and a clad metal part that is bonded to one side of the base member, wherein the clad metal part is etched to have an electrical pattern. The vibration motor according to the present invention includes a rotor that includes a printed-circuit board formed with a clad metal part etched to have an electrical pattern, and a stator that includes a brush contacting the clad metal part.

### CROSS REFERENCE TO RELATED APPLICATION

This application claims the benefit of Korean Patent Application No. 10-2010-0065881, filed on Jul. 8, 2010, entitled “Printed-Circuit Board and Vibration Motor Having The Same” which is hereby incorporated by reference in its entirety into this application.

### BACKGROUND OF THE INVENTION

1. Technical Field

The present invention relates to a printed-circuit board and a vibration motor having the same.

2. Description of the Related Art

Recently, with the increased demand for a vibration motor that generates vibration at the time of receiving a call in a mobile communication terminal, the vibration motor has been developed day by day. A vibration motor that can have improved mechanical characteristics, high efficiency, and a long life span has been developed.

However, a commutator part of a printed-circuit board mounted to a rotation part of a vibration motor is in contact with a brush to have problems in that a life span of the motor is shortened by abrasion and spark due to a mechanical and electrical contact and efficiency is degraded.

Hereinafter, problems of the vibration motor according to the prior art will be described in more detail with reference to the accompanying drawings.

FIG. 1 is a perspective view schematically showing a flat type vibration motor according to the prior art. As shown in the figure, the flat type vibration motor 100 is configured to include a shaft 110, a bearing 120, an armature coil 130, a weight body 140, a magnet 150, an upper substrate 160, a lower substrate 170, a brush 180, and a case 190. A lead wire 200 is connected to an external power supplier (not shown) to transfer power of the power supplier to the lower substrate 170 and supply current to a commutator part of the upper substrate 160 through the brush 180.

Current flows onto the armature coil 130 through the upper substrate 160. In this case, a rotor that includes the bearing 120, the weight body 140, the armature coil 130, and the upper substrate 160 is rotated by an electrical interaction with the two or more magnets 150 having N pole and S pole, and the weight body 140 is eccentrically positioned, such that vibration is generated.

FIG. 2 is a plan view schematically showing a printed-circuit board of the vibration motor of FIG. 1, and FIG. 3 is a cross-sectional view schematically showing a printed-circuit board of the vibration motor of FIG. 1. As shown in the figures, in a printed-circuit board 160 of the vibration motor according to the prior art, a commutator part 161 is formed in a region contacting the brush 180.

More specifically, in the commutator part 161, a copper layer 161b is formed on one side or both sides of a base member 161a and a precious metal layer 161c formed of a gold or hard gold layer is formed on one side of the copper layer 161b. As another embodiment, a copper layer 161b is formed on one side or both sides of a base member 161a and a nickel layer formed on one side of the copper layer 161b in order to supplement strength and a precious metal layer 161c formed of a gold or hard gold layer is formed on one side of nickel layer.

However, as the commutator part 161 of the printed-circuit board 160 like the upper substrate that rotates at high speed is in contact with the brush, the plated precious metal layer 161c also has problems in that a life span of the motor is shortened by abrasion and spark due to a mechanical and electrical contact and performance is degraded.

### SUMMARY OF THE INVENTION

The present invention has been made an effort to provide a vibration motor in which a clad metal part is formed on a commutator part of a printed-circuit board contacting a brush to improve conductivity and abrasion resistance, thereby improving mechanical characteristics and efficiency and preventing a life span of the motor from being shortened.

The present invention has been also made in an effort to provide a vibration motor having a clad metal part that can be simply and efficiently manufactured by being bonded to a printed-circuit board at high temperature and high pressure and patterned by etching.

A printed-circuit board according to the present invention includes: a base member; and a clad metal part that is bonded to one side of the base member, wherein the clad metal part is etched to have an electrical pattern.

The clad metal part of the printed circuit board according to a first embodiment of the present invention includes: a clad base that contacts the base member and is formed with a clad receiving part; and a clad part that is inserted into the clad receiving part.

The clad metal part is formed by forming the clad receiving part to correspond to the clad part by performing biting on one side of the clad base, pressurizing and bonding the clad part to the clad receiving part, and rolling the clad part and the clad base at high temperature and high pressure.

The clad metal part is bonded to the base member by high-temperature and high-pressure pressing.

The clad metal part of the printed circuit board according to a second embodiment of the present invention includes: a clad base that contacts the base member, and a clad part that contacts the clad base.

The clad metal part of the printed circuit board according to a third embodiment of the present invention includes a clad part that contacts the base member.

The clad part is made of a precious metal material including at least one among silver (Ag), gold (Au), palladium (Pd), and platinum (Pt) or an alloy including at least one thereof.

A vibration motor according to the present invention includes: a rotor that includes a printed-circuit board formed with a clad metal part etched to have an electrical pattern; and a stator that includes a brush contacting the clad metal part.

The clad metal part of the vibration motor according to a first embodiment of the present invention includes: a clad base that contacts the base member and is formed with a clad receiving part; and a clad part that is inserted into the clad receiving part.

The clad metal part is formed by forming the clad receiving part to correspond to the clad part 261 by performing biting on one side of the clad base, pressurizing and bonding the clad part to the clad receiving part, and rolling the clad part and the clad base at high temperature and high pressure.

The clad metal part is bonded to the base member by high-temperature and high-pressure pressing.

The clad metal part of the vibration motor according to a second embodiment of the present invention includes: a clad base that contacts the base member; and a clad part that contacts the clad base.

The clad metal part of the vibration motor according to a first embodiment of the present invention includes a clad part that contacts the base member.

The clad part is made of a precious metal material including at least one among silver (Ag), gold (Au), palladium (Pd), and platinum (Pt) or an alloy including at least one thereof.

The rotor includes a printed-circuit board, an armature coil, and an eccentric member, and the stator includes a magnet and a brush.

### BRIEF DESCRIPTION OF THE DRAWINGS

FIG. 1 is a cross-sectional view schematically showing a vibration motor according to the prior art;

FIG. 2 is a plan view schematically showing a printed-circuit board of the vibration motor of FIG. 1;

FIG. 3 is a cross-sectional view schematically showing a printed-circuit board of the vibration motor of FIG. 1;

FIG. 4 is a plan view schematically showing a printed-circuit board of the vibration motor according to the present invention;

FIG. 5 is a cross-sectional view schematically showing the printed-circuit board of FIG. 4;

FIG. 6 is a cross-sectional view schematically showing a clad metal part of a printed-circuit board according to a first embodiment of the present invention;

FIG. 7 is a cross-sectional view schematically showing a clad metal part of a printed-circuit board according to a second embodiment of the present invention;

FIG. 8 is a cross-sectional view schematically showing a clad metal part of a printed-circuit board according to a third embodiment of the present invention;

FIG. 9 is a perspective view schematically showing a step of forming a pattern in a method of manufacturing a printed-circuit board according to the present invention;

FIG. 10 is a cross-sectional view schematically showing a printed-circuit board according to a first embodiment of the present invention;

FIG. 11 is a cross-sectional view schematically showing a printed-circuit board according to a second embodiment of the present invention;

FIG. 12 is a cross-sectional view schematically showing a printed-circuit board according to a third embodiment of the present invention; and

FIG. 13 is a cross-sectional view schematically showing a printed-circuit board according to a fourth embodiment of the present invention.

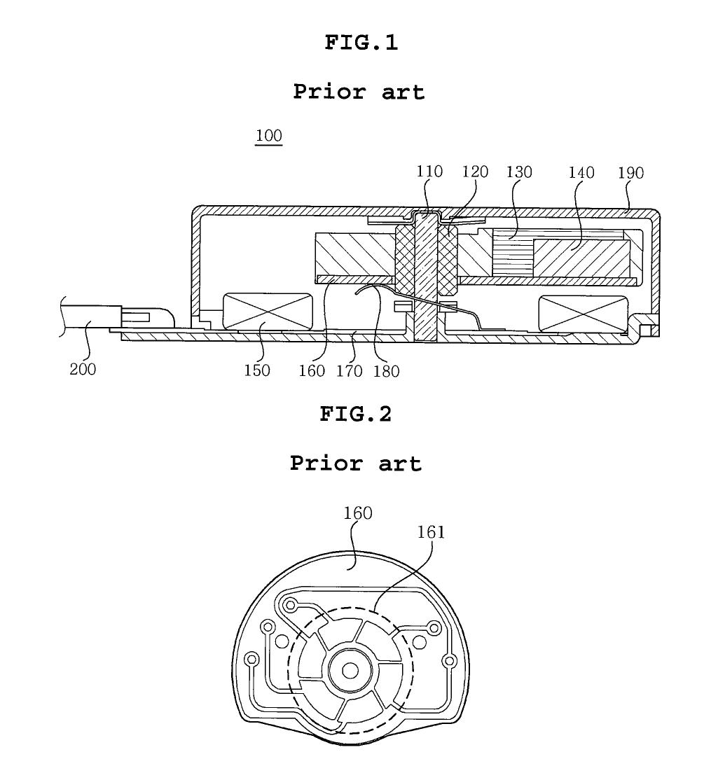

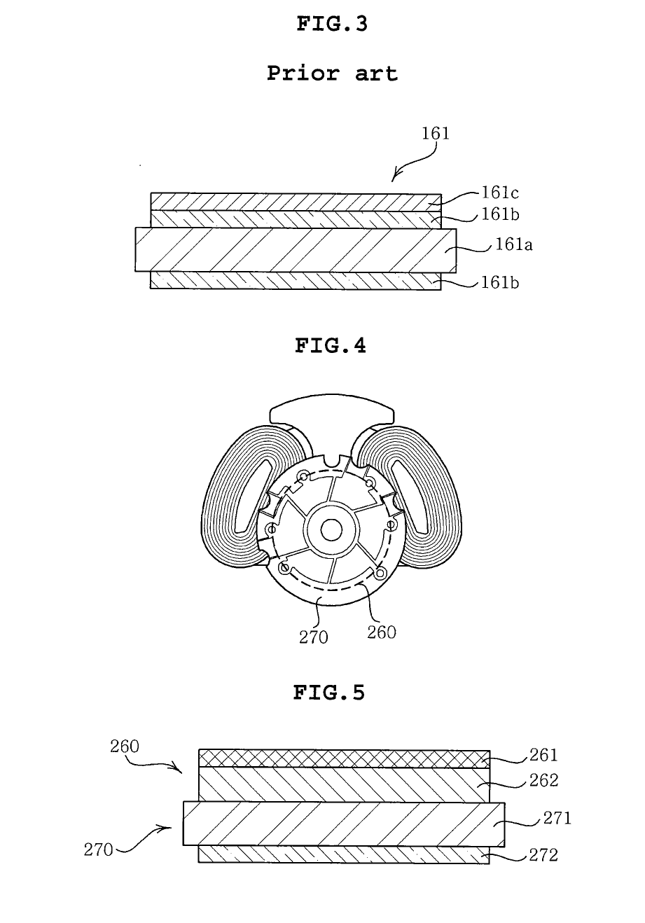

### DESCRIPTION OF THE PREFERRED EMBODIMENTS

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. In the description, the terms “first”, “second”, “one surface”, “the other surface” and so on are used to distinguish one element from another element, and the elements are not defined by the above terms. In describing the present invention, a detailed description of related known functions or configurations will be omitted so as not to obscure the gist of the present invention.

Hereinafter, preferred embodiments of the present invention will be described in detail with reference to the accompanying drawings.

FIG. 4 is a plan view schematically showing a printed-circuit board of the vibration motor according to the present invention, and FIG. 5 is a cross-sectional view schematically showing the printed-circuit board of FIG. 4. As shown in the figures, in a printed-circuit board 270, a clad metal part 260 implemented as a commutator part is formed at a position contacting a brush (not shown).

More specifically, the printed-circuit board 270 includes a base member 271 and a copper layer 272, and the clad metal part 260 is bonded to one side of the base member 271 of the printed-circuit board 270 so as to contact the brush. In this case, the clad metal part may be bonded to the base member in various methods. However, considering that the base member 271 is made of polyimide, epoxy resin, or the like, it is preferable that the clad metal part is bonded to the base member by high-temperate and high-pressure pressing.

The clad metal part 260 includes a clad base 262 and a clad part 261. In addition, it is preferable that the clad base 262 is made of copper or a copper alloy, and the clad part 261 is made of a precious metal materials including at least one among silver (Ag), gold (Au), palladium (Pd), and platinum (Pt) or an alloy including at least one thereof so as to prevent spark generating electrical abrasion with the brush from occurring.

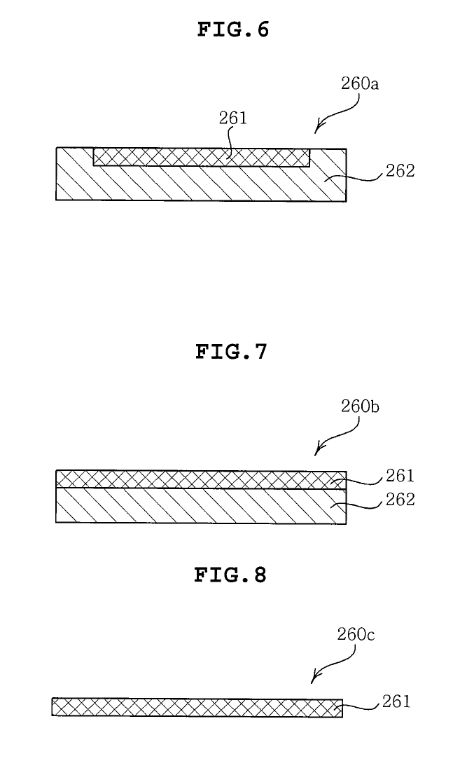

FIG. 6 is a cross-sectional view schematically showing a clad metal part of a printed-circuit board according to a first embodiment of the present invention. As shown in the figure, the clad metal part 260a includes the clad base 262 and the clad part 261. The clad base 262 is formed with a clad receiving part, wherein the clad part 261 is inserted into the clad receiving part.

To this end, the clad receiving part is formed to correspond to the clad part 261 by performing biting on one side of the clad base 262, the clad part 261 is pressed and bonded to the clad receiving part, and the clad part 261 and the clad base 262 are rolled at high temperature and high pressure, thereby forming the clad metal part 260a.

FIG. 7 is a cross-sectional view schematically showing a clad metal part of a printed-circuit board according to a second embodiment of the present invention. As shown in the figure, the clad metal part 260b is formed by directly coupling the clad part 261 to one side of the clad base 262, not forming the clad receiving part, different from the clad base 262 of the clad metal part 260a according to the first embodiment. In this case, the clad part 261 may be bonded to the clad base 262 in various methods such as high-temperature and high-pressure pressing, bonding, or the like.

FIG. 8 is a cross-sectional view schematically showing a clad metal part of a printed-circuit board according to a third embodiment of the present invention. As shown in the figure, the clad metal part 260c is configured of only the clad part 261, not including the clad base 262, different from the clad metal part 260a according to the first embodiment and the clad metal part 260b according to the second embodiment, and is directly bonded to the base member 271 of the printed-circuit board 270 as shown in FIG. 5.

Hereinafter, a method of manufacturing a printed-circuit board according to the present invention will be described.

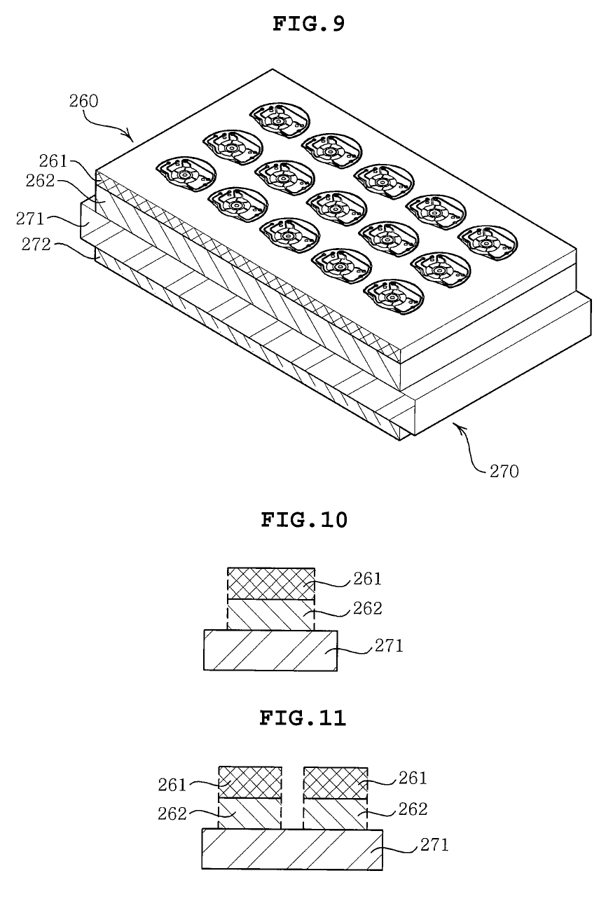

FIG. 9 is a perspective view schematically showing a step of forming a pattern in a method of manufacturing a printed-circuit board according to the present invention; As shown in the figure, the printed-circuit board 270 includes the base member 271 and the copper layer 272, and the clad metal part 260 includes the clad base 262 and the clad part 261, wherein the clad metal part 260 is bonded to the upper portion of the base member 271 by high-temperature and high-pressure pressing. An electrical pattern is formed on the clad metal part 260 and the printed-circuit board 270 using an etching method that is a method of manufacturing a printed-circuit board according to the prior art. More specifically, a via hole is formed by drilling, copper plating, organic film bonding, exposing and developing, and a metal bonded to a base substrate is removed by etching, separating and cleansing, thereby forming a pattern on a printed-circuit board.

FIG. 10 is a cross-sectional view schematically showing a printed-circuit board according to a first embodiment of the present invention, and FIG. 11 is a cross-sectional view schematically showing a printed-circuit board according to a second embodiment of the present invention. When an electrical pattern is formed on the printed circuit board using an etching method as described above, the clad metal part implemented as a commutator part may be formed in single or in plural, including the clad base 262 and the clad part 261, on the upper portion of the base member 271 of the printed circuit board. In addition, the side portion of the clad metal part indicated by a dotted line in the figure represents an etched surface.

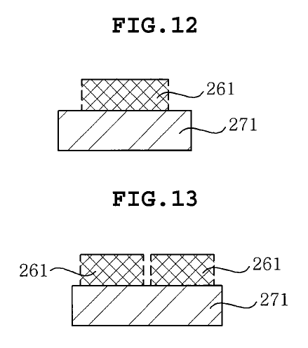

FIG. 12 is a cross-sectional view schematically showing a printed-circuit board according to a third embodiment of the present invention, and FIG. 13 is a cross-sectional view schematically showing a printed-circuit board according to a fourth embodiment of the present invention. When an electrical pattern is formed on the printed circuit board using an etching method as described above, the clad metal part implemented as a commutator part may be formed in a single or in plural, including only the clad part 261, on the upper portion of the base member 271 of the printed circuit board. In this case, it is preferable that the clad part 261 has a same thickness as the clad base, in consideration of abrasion thereof. In addition, the side portion of the clad metal part indicated by a dotted line in the figure represents an etched surface.

As configured above, the clad metal part is formed on the commutator part of the printed-circuit board contacting the brush to improve conductivity and abrasion resistance, thereby making it possible to provide the vibration motor improving mechanical characteristics and efficiency and preventing a life span of the motor from being shortened. Further, the present invention provides the vibration motor having the clad metal part that can be simply and efficiently manufactured by being bonded to a printed-circuit board at high temperature and high pressure and patterned by etching.

According to the present invention, the clad metal part is formed on the commutator part of the printed-circuit board contacting the brush to improve conductivity and abrasion resistance, thereby making it possible to provide the vibration motor improving mechanical characteristics and efficiency and preventing a life span of the motor from being shortened. Further, the present invention provides the vibration motor having the clad metal part that can be simply and efficiently manufactured by being bonded to a printed-circuit board at high temperature and high pressure and patterned by etching.

Although the preferred embodiments of the present invention have been disclosed for illustrative purposes, they are for specifically explaining the present invention and thus a printed-circuit board and a vibration motor having the same according to the present invention are not limited thereto, but those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A printed-circuit board, comprising:
a base member; and
a clad metal part that is bonded to one side of the base member,
wherein the clad metal part is etched to have an electrical pattern.

2. The printed-circuit board as set forth in claim 1, wherein the clad metal part includes:
a clad base that contacts the base member and is formed with a clad receiving part; and
a clad part that is inserted into the clad receiving part.

3. The printed-circuit board as set forth in claim 2, wherein the clad metal part is formed by forming the clad receiving part to correspond to the clad part by performing biting on one side of the clad base, pressurizing and bonding the clad part to the clad receiving part, and rolling the clad part and the clad base at high temperature and high pressure.

4. The printed-circuit board as set forth in claim 1, wherein the clad metal part is bonded to the base member by high-temperature and high-pressure pressing.

5. The printed-circuit board as set forth in claim 1, wherein the clad metal part includes:
a clad base that contacts the base member; and
a clad part that contacts the clad base.

6. The printed-circuit board as set forth in claim 1, wherein the clad metal part includes a clad part that contacts the base member.

7. The printed-circuit board as set forth in claim 1, wherein the clad part is made of a precious metal material including at least one among silver (Ag), gold (Au), palladium (Pd), and platinum (Pt) or an alloy including at least one thereof.

8. A vibration motor, comprising:
a rotor that includes a printed-circuit board formed with a clad metal part etched to have an electrical pattern; and
a stator that includes a brush contacting the clad metal part.

9. The vibration motor as set forth in claim 8, wherein the clad metal part includes:
a clad base that contacts the base member and is formed with a clad receiving part; and
a clad part that is inserted into the clad receiving part.

10. The vibration motor as set forth in claim 9, wherein the clad metal part is formed by forming the clad receiving part to correspond to the clad part by performing biting on one side of the clad base, pressurizing and bonding the clad part to the clad receiving part, and rolling the clad part and the clad base at high temperature and high pressure.

11. The vibration motor as set forth in claim 8, wherein the clad metal part is bonded to the base member by high-temperature and high-pressure pressing.

12. The vibration motor as set forth in claim 8, wherein the clad metal part includes:
a clad base that contacts the base member; and
a clad part that contacts the clad base.

13. The vibration motor as set forth in claim 8, wherein the clad metal part includes a clad part that contacts the base member.

14. The vibration motor as set forth in claim 8, wherein the clad part is made of a precious metal material including at least one among silver (Ag), gold (Au), palladium (Pd), and platinum (Pt) or an alloy including at least one thereof.

15. The vibration motor as set forth in claim 8, wherein the rotor includes a printed-circuit board, an armature coil, and an eccentric member, and the stator includes a magnet and a brush.
